(19) United States
(12) Patent Application Publication
(10) Pub. No.: US 2024/0196640 A1
(43) Pub. Date: Jun. 13, 2024

(54) DISPLAY PANEL

(71) Applicant: Wuhan China Star Iptoelectronics Semiconductor Display Technology Co., Ltd., Wuhan (CN)

(72) Inventors: Yue ZHANG, Wuhan (CN); Lin YANG, Wuhan (CN)

(21) Appl. No.: 17/785,431

(22) PCT Filed: May 23, 2022
(86) PCT No.: PCT/CN2022/094383

§ 371 Date: Jun. 15, 2022

(30) Foreign Application Priority Data
May 7, 2022 (CN) 202210490839.2

(51) Int. Cl. H10K 50/18; H10K 59/126; H10K 59/35

(52) U.S. Cl. CPC H10K 50/181; H10K 59/126; H10K 59/352

(57) ABSTRACT

The present invention relates to a display panel. The material of the first electron blocking layer located in the first sub-pixel area and the second sub-pixel area of the present invention is the same, so that the same mask can be used in the same evaporation chamber to fabricate a first electron blocking layer in the first sub-pixel area and the second sub-pixel area at the same time, thereby saving production costs and reducing fabrication difficulty.

### FIELD OF INVENTION

The present application relates to fields of display panel design, and particularly to a display panel.

### BACKGROUND

Organic light emitting diode (OLED) is an optoelectronic technology that uses organic semiconductor materials to produce reversible color changes under the current drive to achieve colorful display. OLED has the advantages of thinness, high brightness, active light emission, low energy consumption, large viewing angle, fast response, flexibility, wide operating temperature range, low voltage demand, high power saving efficiency, fast response, simple structure, low cost, and almost infinitely high contrast ratio. Therefore, OLED is the most promising new generation display technology due to above advantages.

At present, a way of OLED display in the industry is mainly the technology of combining independent pixels of three primary colors (RGB) into color light. An existing OLED comprises an electron blocking layer (EBL). If an electron blocking layer material with a relatively slow hole mobility of carriers is used, a voltage will increase, resulting in an increase in the power consumption of the OLED device. If an electron blocking layer material with a relatively fast hole mobility of carriers is used, lateral leakage will be caused, which will cause undesired turn-on of other pixels, thereby affecting the display effect of a picture. For example, in the low-brightness mode, there is lateral charge transfer inside the device, and the electron blocking layer is equivalent to a parallel resistance, so that when the red sub-pixel is turned on, the adjacent green sub-pixel is also slightly turned on.

Since the consumption of the red electron blocking layer and the green electron blocking layer is too large, they cannot be combined with the material of the emitting layer (EML). In addition, since the red sub-pixel and the green sub-pixel have the undesired turn-on problem at low gray scales, the red electron blocking layer and the green electron blocking layer cannot be evaporated in the same cavity, resulting in relatively high production costs.

### SUMMARY OF DISCLOSURE

A purpose of the present invention is to provide a display panel, which can solve the problem that the red electron blocking layer and the green electron blocking layer cannot be evaporated in the same cavity, resulting in high production costs.

In order to solve the above problems, the present invention provides a display panel, comprising a plurality of spaced sub-pixel areas and a blocking region located between the plurality of sub-pixel areas, wherein each of the plurality of sub-pixel areas comprises a first sub-pixel area and a second sub-pixel area. The display panel comprises a substrate and a light-emitting layer arranged on a side of the substrate. The light-emitting layer comprises a first electron blocking layer arranged on the substrate and located in the first sub-pixel area, the second sub-pixel area and the blocking region between the first sub-pixel area and the second sub-pixel area; wherein a hole mobility of a material of the first electron blocking layer located in the first sub-pixel area is greater than a hole mobility of the material of at least a part of the first electron blocking layer located in the blocking region; and/or a hole mobility of the material of the first electron blocking layer located in the second sub-pixel area is greater than a hole mobility of the material of at least a part of the first electron blocking layer located in the blocking region.

Furthermore, the display panel further comprises a shielding layer arranged between the substrate and the first electron blocking layer; wherein the shielding layer comprises a first shielding part corresponding to the first sub-pixel area and a second shielding part corresponding to the second sub-pixel area, and a first gap exists between the adjacent first shielding part and the second shielding part; wherein a hole mobility of the material of the first electron blocking layer located in the first sub-pixel area is greater than a hole mobility of the material of the first electron blocking layer corresponding to the first gap; and/or a hole mobility of the material of the first electron blocking layer located in the first sub-pixel area is greater than a hole mobility of the material of the first electron blocking layer corresponding to the first gap.

Furthermore, a width of the first gap is less than or equal to a width of the shielding layer between the adjacent first and second sub-pixels.

Furthermore, a thickness of the first electron blocking layer located in the first sub-pixel area and the second sub-pixel area is the same as a thickness of the first electron blocking layer located in the blocking region.

Furthermore, each of the plurality of sub-pixel areas further comprises a third sub-pixel area. The light-emitting layer further comprises a second electron blocking layer arranged on the substrate and located in the third sub-pixel area, and a second gap exists between the second electron blocking layer and the first electron blocking layer; and a hole mobility of a material of the second electron blocking layer in the third sub-pixel area is greater than a hole mobility of the material of at least a part of the first electron blocking layer the blocking region.

Furthermore, the first sub-pixel area is a green sub-pixel area, the second sub-pixel area is a red sub-pixel area, and the third sub-pixel area is a blue sub-pixel area.

Furthermore, the light emitting layer further comprises a first common layer arranged between the substrate and the first electron blocking layer and located in the sub-pixel area and the blocking region; a sum of the hole mobility of the material of the first electron blocking layer and the hole mobility of the material of the first common layer located in the first sub-pixel area is greater than a sum of the hole mobility of the material of the at least a part of the first electron blocking layer and the hole mobility of the material of the first common layer located in the blocking region; and/or a sum of the hole mobility of the material of the first electron blocking layer and the hole mobility of the material of the first common layer located in the second sub-pixel area is greater than a sum of the hole mobility of the material of the at least a part of the first electron blocking layer and the hole mobility of the material of the first common layer located in the blocking region.

Furthermore, the light emitting layer further comprises a second common layer arranged between the first common layer and the first electron blocking layer and located in the sub-pixel area and the blocking region; a sum of the hole mobility of the material of the first electron blocking layer, the hole mobility of the material of the first common layer and the hole mobility of the material of the second common layer located in the first sub-pixel area is greater than a sum of the hole mobility of the material of the at least a part of the first electron blocking layer, the hole mobility of the material of the first common layer and the hole mobility of the material of the second common layer located in the blocking region; and/or a sum of the hole mobility of the material of the first electron blocking layer, the hole mobility of the material of the first common layer and the hole mobility of the material of the second common layer located in the second sub-pixel area is greater than a sum of the hole mobility of the material of the at least a part of the first electron blocking layer, the hole mobility of the material of the first common layer and the hole mobility of the material of the second common layer located in the blocking region.

Furthermore, the hole mobility of the material of the first electron blocking layer located in the first sub-pixel area and the second sub-pixel area is in the range of 1E4 cm²/v·s-1E2 cm²/v·s, and the hole mobility of the material of the at least a part of the first electron blocking layer located in the blocking region is less than 1E6 cm²/v·s.

Furthermore, a Homo energy level of the material of the first electron blocking layer ranges from 5.50 eV to 6.00 eV.

Furthermore, the first electron blocking layer located in the first sub-pixel area and the blocking region both comprises a plurality of elements that are the same, and a molecular structure formed of the plurality of elements located in the first sub-pixel area and in the blocking region are different; and/or the first electron blocking layer located in the second sub-pixel area and the blocking region both comprises a plurality of elements that are the same, and a molecular structure formed of the plurality of elements located in the second sub-pixel area and in the blocking region are different.

Accordingly, the embodiments of the present invention provide following beneficial effects.

The material of the first electron blocking layer located in the first sub-pixel area and the second sub-pixel area of the present invention is the same, so that the same mask can be used in the same evaporation for fabricating a first electron blocking layer in the first sub-pixel area and the second sub-pixel area, thereby saving production costs and reducing the difficulty of fabrication. A blocking region is irradiated by a laser process, so that the irradiated first electron blocking layer in the blocking region is passivated, a hole mobility of the material of the irradiated first electron blocking layer located in the blocking region is reduced, and a lateral charge transfer between the first light-emitting unit and the second light-emitting unit is blocked, which ultimately prevents the undesired turn-on phenomenon at low gray scales. By arranging a shielding layer on a side of the substrate in the sub-pixel area away from the first electron blocking layer, the laser is prevented from damaging the film layers such as the first electron blocking layer in the sub-pixel areas so as to avoid affecting the performance of the display panel.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a schematic plan view of a display panel of the present invention.

FIG. 2 is schematic cross-sectional diagram along the A-A in FIG. 1.

FIG. 3 is a structural schematic diagram of a display panel of the present invention.

FIG. 4 is a schematic plan view of the first mask plate of the present invention.

FIG. 5 is a schematic diagram showing a laser irradiating a blocking region at a first gap of the present invention.

### DESCRIPTION OF REFERENCE NUMBERS

100: display panel; 101: sub-pixel area; 102: blocking region; 1011: first sub-pixel area; 1012: second sub-pixel area; 1013: third sub-pixel area; 1: substrate; 2: light-emitting layer; 21: first electrode; 22: pixel definition layer; 23: first common layer; 24: second common layer; 25: first electron blocking layer; 26: first light-emitting unit; 27: second light-emitting unit; 28: second electrode; 29: second electron blocking layer; 30: third light-emitting unit; 3: shielding layer; 31: first shielding part; 32: second shielding part; 33: first gap; 4: first mask plate; 41: light transmitting hole.

### DETAILED DESCRIPTION

The preferred embodiments of the present invention will be described in detail below with reference to the accompanying drawings, so as to fully introduce the technical content of the present invention to those skilled in the art, to exemplify the implementation of the present invention, to make the technical content disclosed in the present invention clearer, and to make the present invention clearer. Those skilled in the art will more readily understand how to implement the present invention. However, the present invention can be embodied in many different forms of embodiments, the protection scope of the present invention is not limited to the embodiments mentioned herein, and the description of the following embodiments is not intended to limit the scope of the present invention.

The directional terms mentioned in the present invention, such as “up”, “down”, “front”, “rear”, “left”, “right”, “inside”, “outside”, “side”, etc., are only attached. Directions in the drawings and the directional terms used herein are used to explain and describe the present invention, rather than to limit the protection scope of the present invention.

In the drawings, identical structural components are assigned with the same numeral references, and structurally or functionally similar components are assigned with like numeral references throughout. In addition, for ease of understanding and description, a size and thickness of each component shown in the accompanying drawings are arbitrarily shown, and the present invention does not limit the size and thickness of each component.

### EMBODIMENTS

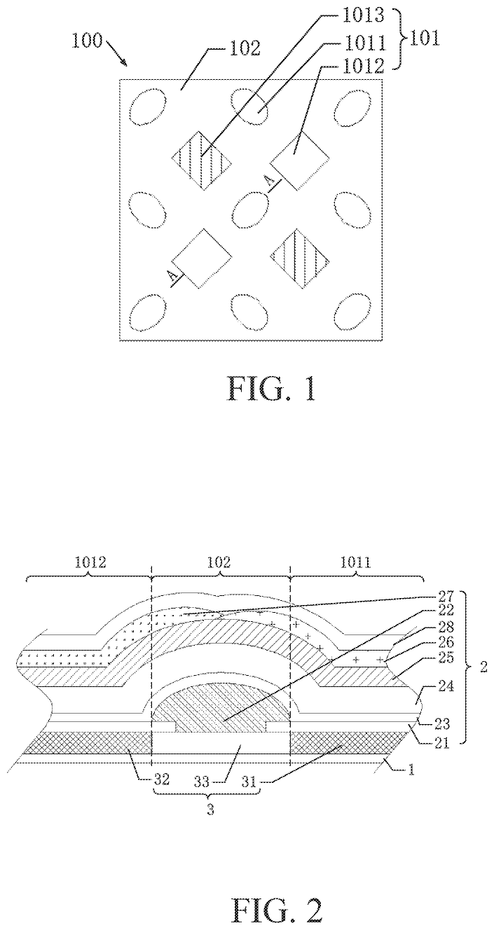

As shown in FIG. 1, the present embodiment provides a display panel 100. The display panel 100 comprises a plurality of sub-pixel areas 101 disposed at intervals and a blocking region 102 disposed between the adjacent sub-pixel areas 101.

As shown in FIG. 1, each of the sub-pixel areas 101 comprises a first sub-pixel area 1011, a second sub-pixel area 1012 and a third sub-pixel area 1013. In the present embodiment, the first sub-pixel area 1011 is a green sub-pixel area, the second sub-pixel area 1012 is a red sub-pixel area, and the third sub-pixel area 1013 is a blue sub-pixel area.

As shown in FIG. 2 and FIG. 3, the display panel 100 comprises a substrate 1 and a light-emitting layer 2 arranged on the substrate 1.

As shown in FIG. 2 and FIG. 3, the light-emitting layer 2 comprises a plurality of first electrodes 21, a pixel definition layer 22, a first common layer 23, a second common layer 24, a first electron blocking layer 25, a first light-emitting unit 26, a second light-emitting unit 27, and a second electrode 28.

A material of the substrate 1 is one or more of glass, polyimide, polycarbonate, polyethylene terephthalate and polyethylene naphthalate, so the substrate 1 may have better impact resistance that can effectively protect the display panel 100.

The first electrodes 21 are arranged on the substrate 1 of the sub-pixel area 101 at intervals. A material of the first electrodes 21 may be metal. In the present embodiment, the material of the first electrodes 21 is silver (Ag). Therefore, the first electrodes 21 have good electrical conductivity. In fact, a thin film transistor layer (not shown) is also provided between the substrate 1 and the first electrodes 21.

The pixel definition layer 22 is arranged on the substrate 1 of the blocking region 102. The pixel definition layer 22 is mainly used to block light of different colors emitted by the light emitting units in the adjacent two sub-pixel areas from cross-talking so as to avoid affecting the display effect.

The first common layer 23 is arranged on a side of the first electrode 21 away from the substrate 1 and located in the sub-pixel area 101 and the blocking region 102. In the present embodiment, the first common layer 23 is a hole injection layer (HIL). The first common layer 23 may be composed of an inorganic or organic material, including but not limited to various elements, compounds and their composite or mixed materials, such as small organic molecules, polymers, halogen compounds, oxygen compounds, nitrogen compounds, carbon compounds, or composite or mixed materials composed of the above materials, etc.

A sum of the hole mobility of the first electron blocking layer 25 and the hole mobility of the first common layer 23 in at least a part of the blocking region 102 is smaller than a sum of the hole mobility of the first electron blocking layer 25 and the hole mobility of the first common layer in the first sub-pixel area 1011, and is smaller than a sum of the hole mobility of the first electron blocking layer 25 and the hole mobility of the first common layer 23 in the second sub-pixel area 1012. That is, by irradiating the blocking region 102 with a laser, the material of the irradiated first common layer 23 can be deteriorated, thereby reducing the sum of the hole mobility of the material of the irradiated first electron blocking layer 25 and the hole mobility of the first common layer 23 located in the blocking region 102.

The second common layer 24 is arranged on a side of the first common layer 23 away from the substrate 1 and located in the sub-pixel area 101 and the blocking region 102. In the present embodiment, the second common layer 24 is a hole transport layer (HTL). The second common layer 24 can be composed of an inorganic or organic material, including but not limited to various elements, compounds and their composite or mixed materials, such as small organic molecules, polymers, halogen compounds, oxygen compounds, nitrogen compounds, carbon compounds, or composite or mixed materials composed of the above materials, etc.

A sum of the hole mobility of the first electron blocking layer 25, the hole mobility of the first common layer 23 and the hole mobility of the second common layer 24 in at least a part of the blocking region 102 is smaller than a sum of the hole mobility of the first electron blocking layer 25, the hole mobility of the first common layer 23 and the hole mobility of the second common layer 24 in the first sub-pixel area 1011, and is smaller than a sum of the hole mobility of the first electron blocking layer 25, the hole mobility of the first common layer 23 and the hole mobility of the second common layer 24 in the second sub-pixel area 1012. That is, irradiating the blocking region 102 with a laser can also lead to the deterioration of the materials of the irradiated first common layer 23 and the second common layer 24, reducing the sum of the hole mobility of the materials of the irradiated first electron blocking layer 25, the hole mobility of the first common layer 23 and the hole mobility of the second common layer 24 located in the blocking region 102.

The first electron blocking layer 25 is arranged on a surface of the second common layer 24 on a side away from the substrate 1. The first electron blocking layer 25 is located in the first sub-pixel area 1011, the second sub-pixel area 1012, and the blocking region 102 between the first sub-pixel area 1011 and the second sub-pixel area 1012. Materials and thicknesses of the first electron blocking layer 250 in the first sub-pixel area 1011, the second sub-pixel area 1012 and the blocking region 102 between the first sub-pixel area 1011 and the second sub-pixel area 1012 are the same. As a result, the same mask can be used in the same vaporization chamber to fabricate the first electron blocking layer in the first sub-pixel area 1011, the second sub-pixel area 1012, and the first sub-pixel area 1011 and the second sub-pixel area 1012 at the same time, thereby saving production costs and reducing fabrication difficulty.

A range of the hole mobility of the material of the first electron blocking layer 25 located in the first sub-pixel area 1011 and the second sub-pixel area 1012 is between 1E4 cm²/v·s-1E2 cm²/v·s, and a HOMO energy level thereof ranges from 5.50 eV to 6.00 eV. Therefore, it is ensured that the first electron blocking layer 25 located in the first sub-pixel area 1011 and the second sub-pixel area 1012 has a greater hole mobility, thereby reducing voltage and power consumptions.

The hole mobility of the material of the first electron blocking layer 25 located in the first sub-pixel area 1011 and the second sub-pixel area 1012 is greater than the hole mobility of the material of the at least a part of the first electron blocking layer 25 located in the blocking region 102. The hole mobility of the material of at least a part of the first electron blocking layer 25 located in the blocking region 102 is less than 1E6 cm²/v·s. In the present embodiment, the blocking region 102 is irradiated by a laser process, so that the irradiated first electron blocking layer 25 of the blocking region 102 is deteriorated. That is, a molecular formula of the material of the irradiated first electron blocking layer 25 in the blocking region 102 is changed from the original macromolecular structure to a small molecular structure (specifically, it can be measured by means such as TOF-SIMS) so that it is passivated and the charge transfer between molecules is blocked. The hole mobility of the material of the irradiated first electron blocking layer 25 in the blocking region 102 is reduced, thereby blocking the lateral charge transferring between the first light emitting unit 26 and the second light emitting unit 27, and finally preventing the undesired turn-on phenomenon at low gray scales.

Specifically, the first electron blocking layer 25 located in the first sub-pixel area 1011 and the blocking region 102 comprises the same multiple elements, and since the molecular structures formed by the plurality of elements in the first sub-pixel area 1011 and the blocking region 102 are different (in the blocking region 102, due to the irradiation of the laser process, the molecular structure is passivated from a macromolecule to a small molecular structure, and the charge transfer between the molecules is blocked).

Specifically, the first electron blocking layer 25 located in the second sub-pixel area 1012 and in the blocking region 102 comprises the same multiple elements, and the molecular structures formed by the multiple elements located in the second sub-pixel area 1012 and the blocking region 102 are different (in the blocking region 102, the molecular structures are passivated from a macromolecule to a small molecular structure due to the irradiation of the laser process, and the charge transfer between the molecules is blocked).

The first light-emitting unit 26 is arranged on a surface of the first electron blocking layer 25 on a side away from the substrate 1 and located in the first sub-pixel area 1011. In the present embodiment, the first light-emitting unit 26 is a green light-emitting unit.

The second light-emitting unit 27 is arranged on a surface of the first electron blocking layer 25 on a side away from the substrate 1 and located in the second sub-pixel area 1012. In the present embodiment, the second light-emitting unit 27 is a red light-emitting unit.

The second electrode 28 is arranged on a surface of the first light emitting unit 26 and the second light emitting unit 27 away from the substrate 1 and extends to over the first electron blocking layer 25 of the blocking region 102.

As shown in FIG. 3, the light-emitting layer 2 further comprises a second electron blocking layer 29 and a third light-emitting unit 30.

The second electron blocking layer 29 is arranged on the substrate 1 and located in the third sub-pixel area 1013. In the present embodiment, the material of the first electron blocking layer 25 is different from the material of the second electron blocking layer 29. A second gap exists between the second electron blocking layer 29 and the first electron blocking layer 25. A hole mobility of the material of the second electron blocking layer 29 located in the third sub-pixel area 1013 is greater than a hole mobility of the material of at least a part of the first electron blocking layer 25 located in the blocking region 102. Therefore, lateral transport of holes and the undesired turn-on phenomenon at low gray levels resulted from contacts between the first electron blocking layer 25 and the second electron blocking layer 29 can be prevented.

The third light-emitting unit 30 is arranged on a surface of the second electron blocking layer 29 on a side away from the substrate 1 and located in the third sub-pixel area 1013. In the present embodiment, the third light-emitting unit 30 is a blue light-emitting unit.

In fact, the light-emitting layer 2 may further comprise a hole blocking layer (HBL), an electron transport layer (ETL), an electron injection layer (EIL) and other film layers.

In fact, the display panel 100 may further comprise a light coupling output layer (CPL) and a thin film encapsulation layer (TFE).

As shown in FIG. 2 and FIG. 3, a shielding layer 3 is disposed between the substrate 1 and the first electron blocking layer 25, and it is located in the sub-pixel area 101. In the present embodiment, the shielding layer 3 is disposed between the substrate 1 and the first electrodes 21. A material of the shielding layer 3 comprises one or more of aluminum, platinum, palladium, silver, magnesium, gold, nickel, neodymium, iridium, chromium, lithium, calcium, molybdenum, titanium, tungsten and copper.

The shielding layer 3 comprises a first shielding part 31 corresponding to the first sub-pixel area 1011 and a second shielding part 32 corresponding to the second sub-pixel area 1012, and a first gap 33 exists between the adjacent first shielding part 31 and the second shielding part 32. The first shielding part 31 is also corresponding to the third sub-pixel area 1013, the blocking region 102 between the third sub-pixel area 1013 and the first sub-pixel area 1011, and the blocking region 102 between the second sub-pixel area 1012 and the third sub-pixel area 1013.

A width of the first gap 33 is smaller than or equal to a width of the blocking region 102 between the adjacent first sub-pixel 1011 and the second sub-pixel 1012. In the present embodiment, the width of the first gap 33 is smaller than the width of the blocking region 102 between the adjacent first sub-pixel 1011 and the second sub-pixel 1012. That is, a part of the blocking region 102 between the first sub-pixel 1011 and the second sub-pixel area 1012 is irradiated by a laser to reduce the hole mobility of the irradiated material of the film layer corresponding to the first gap 33, thereby blocking the lateral charge transfer between the first light-emitting unit 26 and the second light-emitting unit 27 to ultimately prevent the undesired turn-on phenomenon at low gray scales.

The hole mobility of the material of the first electron blocking layer 25 located in the first sub-pixel area 1011 is greater than the hole mobility of the material of the first electron blocking layer 25 corresponding to the first gap 33. The hole mobility of the material of the first electron blocking layer 25 located in the second sub-pixel area 1012 is greater than the hole mobility of the material of the first electron blocking layer 25 corresponding to the first gap 33.

The first shielding part 31 and the second shielding part 32 of the shielding layer 3 are used to prevent the laser from damaging the film layers such as the first electron blocking layer 25 in the sub-pixel area 101 to avoid affecting the performance of the display panel 100. In other embodiments, the blocking layer 3 may also be removed according to specific conditions, and a high-precision fine metal mask (Fine Metal Mask, FMM) is used to perform the laser process.

As shown in FIG. 1, the present embodiment also provides a method of fabricating the display panel 100 of the present embodiment, which comprises following steps: defining a plurality of spaced sub-pixel areas 101 on a substrate 1 and a blocking region 102 between the adjacent sub-pixel areas 101. The sub-pixel areas 101 comprise a first sub-pixel area 1011, a second sub-pixel area 1012 and a third sub-pixel area 1013.

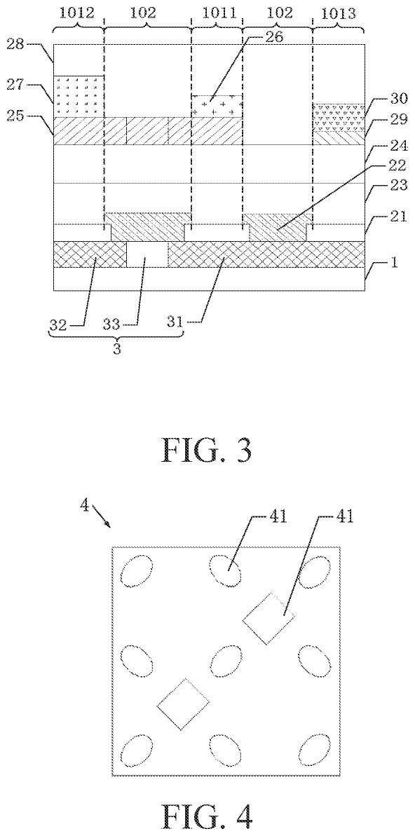

As shown in FIG. 2, FIG. 3, and FIG. 4, the method of fabricating the display panel 100 further comprises forming the first electron blocking layer 25 on the substrate 1 in the first sub-pixel area 1011, the second sub-pixel area 1012 and the blocking region 102 between the pixel region 1011 and the second sub-pixel area 1012 using the first mask plate 4.

As shown in FIG. 4, the first mask plate 4 has a plurality of light transmitting holes 41. Projections of the first sub-pixel area 1011, the second sub-pixel area 1012, and the blocking region 102 between the first sub-pixel area 1011 and the second sub-pixel area 1012 on the substrate 1 fall within projections of the light transmitting holes 41 on the substrate 1. The projection of the third sub-pixel area 1013 on the substrate 1 is away from the projections of the light transmitting holes 41 on the substrate 1. In the present embodiment, the projections of the light transmitting holes 41 on the substrate 1 are completely overlapped with the projections of the first sub-pixel area 1011, the second sub-pixel area 1012, the first sub-pixel area 1011 and the second sub-pixel area 1011, and the blocking regions 102 between the pixel regions 1012 on the substrate 1. In this way, the first mask plate 4 can be used in the same vaporization chamber at the same time to form the first electron blocking layer 25 in the first sub-pixel area 1011, the second sub-pixel area 1012, and between the first sub-pixel area 1011 and the second sub-pixel area 1012, which can save the production costs. In other embodiments, the projections of the light transmitting holes 41 on the substrate 1 may be enlarged, as long as the projections of the light transmitting hole 41 on the substrate are away from the projection of the third sub-pixel area 1013 on the substrate 1.

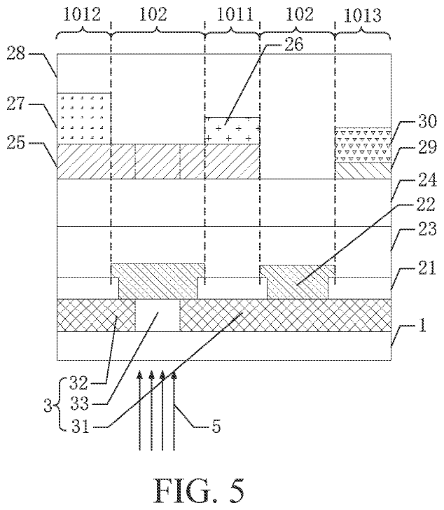

As shown in FIG. 5, the method of the display panel 100 further comprises fabricating a shielding layer 3 between the substrate 1 and the first electrodes 21, and the shielding layer 3 is located in the sub-pixel areas 101. The shielding layer 3 comprises a first shielding part 31 corresponding to the first sub-pixel area 1011 and a second shielding part 32 corresponding to the second sub-pixel area 1012, and a first gap 33 exists between the adjacent first shielding part 31 and the second shielding part 32. The first shielding part 31 further corresponds to the third sub-pixel area 1013, the blocking region 102 between the third sub-pixel area 1013 and the first sub-pixel area 1011, the third sub-pixel area 1013 and the second sub-pixel area 1012 of the blocking regions 102. The first shielding part 31 and the second shielding part 32 of the shielding layer 3 are used to prevent the laser from damaging the film layers such as the first electron blocking layer 25 in the sub-pixel area 101 to avoid affecting the performance of the display panel 100.

As shown in FIG. 5, the method of fabricating the display panel 100 further comprises irradiating the first electron blocking layer 25 located in the blocking region 102 and corresponding to the first gap 33 with a laser 5, and making the hole mobility of the material of the first electron blocking layer 25 in the first sub-pixel areas 1011 and the second sub-pixel area 1012 greater than the hole mobility of the material of the first electron blocking layer 25 in the blocking region 102 corresponding to the first gap 33. The blocking region 102 is irradiated by a laser process, so that the first electron blocking layer 25 corresponding to the first gap 33 in the irradiated blocking region 102 is deteriorated, that is, molecular formula (specifically, can be measured by means such as TOF-SIMS) of the material of the first electron blocking layer 25 corresponding to the first gap 33 is changed to passivated thereof, and the mobility of the material of the first electron blocking layer 25 corresponding to the first gap 33 in the irradiated blocking region 102 is reduced, thereby blocking the lateral charge transfer between the first light-emitting unit 26 and the second light-emitting unit 27, and finally preventing the undesired turn-on phenomenon at low gray scales.

Specifically, laser irradiation can be performed with reference to the parameters in Table 1.

TABLE 1

| | Wave- | Fre- | | Spot | | Number |
|---|---|---|---|---|---|---|
| Laser | length/ | quency/ | | Diameter/ | Processing | of |
| Type | nm | KHz | Power | um | Method | Pulses |
| Femto | 1030 | 100 | 3%-20% | 5-15 | Block | 1-5 |
| | | | | | Shot | |

Furthermore, a display panel provided by the present application has been introduced in detail above, and the principles and implementations of the present application are described with specific examples. The descriptions of the above embodiments are only used to help understand the method of the present application and its core idea. At the same time, for those skilled in the art, according to the idea of the application, there will be changes in the specific implementation and application scope and are not considered as limitation of the present application.

What is claimed is:

1. A display panel, comprising a plurality of spaced sub-pixel areas and a blocking region located between the plurality of sub-pixel areas, wherein each of the plurality of sub-pixel areas comprises a first sub-pixel area and a second sub-pixel area; and
wherein the display panel comprises:
a substrate; and
a light-emitting layer arranged on a side of the substrate, wherein the light-emitting layer comprises:
a first electron blocking layer arranged on the substrate and located in the first sub-pixel area, the second sub-pixel area and the blocking region between the first sub-pixel area and the second sub-pixel area;
wherein a hole mobility of a material of the first electron blocking layer located in the first sub-pixel area is greater than a hole mobility of the material of at least a part of the first electron blocking layer located in the blocking region; and/or
a hole mobility of the material of the first electron blocking layer located in the second sub-pixel area is greater than a hole mobility of the material of at least a part of the first electron blocking layer located in the blocking region.

2. The display panel according to claim 1, further comprising:
a shielding layer disposed between the substrate and the first electron blocking layer;
wherein the shielding layer comprises a first shielding part corresponding to the first sub-pixel area and a second shielding part corresponding to the second sub-pixel area, and a first gap exists between the adjacent first shielding part and the second shielding part;
wherein a hole mobility of the material of the first electron blocking layer located in the first sub-pixel area is greater than a hole mobility of the material of the first electron blocking layer corresponding to the first gap; and/or
a hole mobility of the material of the first electron blocking layer located in the first sub-pixel area is greater than a hole mobility of the material of the first electron blocking layer corresponding to the first gap.

3. The display panel according to claim 2, wherein a width of the first gap is less than or equal to a width of the shielding layer between the adjacent first and second sub-pixels.

4. The display panel according to claim 1, wherein a thickness of the first electron blocking layer located in the first sub-pixel area and the second sub-pixel area is the same as a thickness of the first electron blocking layer located in the blocking region.

5. The display panel according to claim 1, wherein each of the plurality of sub-pixel areas further comprises a third sub-pixel area,
wherein the light-emitting layer further comprises:
a second electron blocking layer arranged on the substrate and located in the third sub-pixel area, and a second gap exists between the second electron blocking layer and the first electron blocking layer; and
a hole mobility of a material of the second electron blocking layer in the third sub-pixel area is greater than a hole mobility of the material of at least a part of the first electron blocking layer the blocking region.

6. The display panel according to claim 5, wherein the first sub-pixel area is a green sub-pixel area, the second sub-pixel area is a red sub-pixel area, and the third sub-pixel area is a blue sub-pixel area.

7. The display panel according to claim 1, wherein the light emitting layer further comprises:
a first common layer arranged between the substrate and the first electron blocking layer and located in the sub-pixel area and the blocking region;
a sum of the hole mobility of the material of the first electron blocking layer and the hole mobility of the material of the first common layer located in the first sub-pixel area is greater than a sum of the hole mobility of the material of the at least a part of the first electron blocking layer and the hole mobility of the material of the first common layer located in the blocking region; and/or
a sum of the hole mobility of the material of the first electron blocking layer and the hole mobility of the material of the first common layer located in the second sub-pixel area is greater than a sum of the hole mobility of the material of the at least a part of the first electron blocking layer and the hole mobility of the material of the first common layer located in the blocking region.

8. The display panel of claim 7, wherein the light emitting layer further comprises:
a second common layer arranged between the first common layer and the first electron blocking layer and located in the sub-pixel area and the blocking region;
a sum of the hole mobility of the material of the first electron blocking layer, the hole mobility of the material of the first common layer and the hole mobility of the material of the second common layer located in the first sub-pixel area is greater than a sum of the hole mobility of the material of the at least a part of the first electron blocking layer, the hole mobility of the material of the first common layer and the hole mobility of the material of the second common layer located in the blocking region; and/or
a sum of the hole mobility of the material of the first electron blocking layer, the hole mobility of the material of the first common layer and the hole mobility of the material of the second common layer located in the second sub-pixel area is greater than a sum of the hole mobility of the material of the at least a part of the first electron blocking layer, the hole mobility of the material of the first common layer and the hole mobility of the material of the second common layer located in the blocking region.

9. The display panel according to claim 1, wherein the hole mobility of the material of the first electron blocking layer located in the first sub-pixel area and the second sub-pixel area is in the range of 1E4 cm²/v·s-1E2 cm²/v·s, and the hole mobility of the material of the at least a part of the first electron blocking layer located in the blocking region is less than 1E6 cm²/v·s.

10. The display panel according to claim 1, wherein a Homo energy level of the material of the first electron blocking layer ranges from 5.50 eV to 6.00 eV.

11. The display panel according to claim 1, wherein:
the first electron blocking layer located in the first sub-pixel area and the blocking region both comprises a plurality of elements that are the same, and a molecular structure formed of the plurality of elements located in the first sub-pixel area and in the blocking region are different; and/or,
the first electron blocking layer located in the second sub-pixel area and the blocking region both comprises a plurality of elements that are the same, and a molecular structure formed of the plurality of elements located in the second sub-pixel area and in the blocking region are different.
